(19) United States
(12) Patent Application Publication
(10) Pub. No.: US 2004/0201083 A1
(43) Pub. Date: Oct. 14, 2004

(54) Hard-macro and semiconductor integrated circuit including the same

(75) Inventor: Masanao Yokoyama, Kawasaki-shi (JP)

Correspondence Address: YOUNG & THOMPSON, 745 SOUTH 23RD STREET 2ND FLOOR, ARLINGTON, VA, 22202

(73) Assignee: NEC ELECTRONICS CORPORATION, KAWASAKI-SHI (JP)

(21) Appl. No.: 10/820,755

(22) Filed: Apr. 9, 2004

(30) Foreign Application Priority Data
Apr. 11, 2003 (JP) 2003-107682
Mar. 5, 2004 (JP) 2004-062213

(51) Int. Cl. H01L 21/00

(52) U.S. Cl. 257/666

(57) ABSTRACT

A hard-macro arranged on a semiconductor chip for constituting a part of a semiconductor integrated circuit includes at least one wire passing therethrough. The wire is formed in the hard-macro before the hard-macro is arranged on the semiconductor chip, and the wire starts a first outer edge of the hard-macro and terminates at a second outer edge of the hard-macro intersecting with the first outer edge.

### BACKGROUND OF THE INVENTION

1. Field of the Invention

The invention relates to a hard-macro, a semiconductor integrated circuit including the hard-macro, a floor-planner for analyzing a floor-plan of a semiconductor integrated circuit including the hard-macro, and a program for causing a computer to analyze a floor-plan of the semiconductor integrated circuit.

2. Description of the Related Art

Recently, a semiconductor integrated circuit is requested to be fabricated in a larger scale and in higher integration, and further requested to be developed in a shorter period of time.

Some of semiconductor integrated circuits are called a building block type semiconductor integrated circuit. When a building block type semiconductor integrated circuit is fabricated, a cell or block into which various functional circuits are integrated is called a building block, and a plurality of building blocks is stored in a memory as a library. Necessary blocks among building blocks stored in a memory are arranged on a semiconductor chip, and then, the blocks are electrically connected to one another through wires.

Such a building block type semiconductor integrated circuit includes a semi-custom IC such as a cell base integrated circuit (CBIC), and a full-custom IC, for instance.

In a layout or floor-plan of a semiconductor integrated circuit, blocks or hard-macros are arranged on a semiconductor chip with an area of the chip and signal delay being taken into consideration. An area between hard-macros is used as an area in which wires are arranged.

In a floor-plan, wires cannot often pass through an area in which a hard-macro has been already arranged in a semiconductor integrated circuit. For instance, when a first hard-macro and a second hard-macro are planned to be electrically connected to each other through wires, if a third hard-macro is located between the first and second hard-macros, it would be impossible for the wires to pass through the third hard-macro. Cases in which a wire cannot pass through a desired area include a case in which it is not allowed to arrange a wire such that cross-talk is not caused between the wire and a cell constituting a hard-macro, and a case in which the wire and wires of a hard-macro are short-circuited with each other.

If a wire is designed to bypass the third hard-macro in the above-mentioned cases, a wire length would be unavoidably increased with the result of difficulty in timing convergence. Thus, it would be necessary to make a layout or floor-plan again, resulting in an increase in turn-around-time (TAT).

Japanese Patent Application Publication No. 9-64190 (A) has suggested an embedded-array type LSI in which a wire is designed to pass through a hard-macro area without bypassing a hard-macro such that the wire is not short-circuited with wires of the hard-macro. In the suggested LSI, the wire and wires of the hard-macro are re-connected to each other in the hard-macro area, ensuring reduction in wires to bypass the hard-macro. The wire is designed to pass through edges of the hard-macro facing each other.

However, a wire is designed to extend from a first outer edge of a hard-macro to a second outer edge facing the first outer edge in the above-identified Publication. For instance, as illustrated in FIG. 1, if a designer wants a wire to extend from a first outer edge 501 of a hard-macro 500 to a second outer edge 502 extending perpendicularly to the first outer edge 501, it would be necessary to arrange a wire 504 to bypass the hard-macro 500, because it is not possible to arrange a wire 503 passing through the hard-macro 500. Thus, the above-identified Publication cannot provide a solution to the problem that a wire cannot pass through a hard-macro area.

In addition, since it is necessary to space hard-macros 600 and 700 from the hard-macro 500 in order to ensure an area in which the wire 604 is to be arranged, there would be caused a loss in a chip area, which further causes an increase in a chip area and insufficient integration density of a semiconductor integrated circuit.

Hard-macros may be grouped into a first group of hard-macros arranged on a semiconductor chip predominantly in a specific area, such as a random access memory (RAM), and a second group of hard-macros necessary to be arranged in a specific area on a semiconductor chip, such as a phase-locked loop (PLL) circuit which is necessary to be arranged in the vicinity of input/output pads (I/O area).

The above-mentioned first group of hard-macros is necessary to be spaced away from adjacent hard-macros in order to ensure an area in which wires are to be arranged, and has a problem that wires has to be arranged in a high density between hard-macros. Similarly, the above-mentioned second group of hard-macros is necessary to be spaced away from I/O pads in order to ensure an area in which wires are to be arranged.

When a floor-plan is designed, it is difficult at an early stage to determine how much area is necessary for arranging wires therein between hard-macros. Hence, if hard-macros are spaced away from each other more than necessary, there would be caused a loss in a chip area and insufficient integration density of a semiconductor integrated circuit. To the contrary, if hard-macros are arranged too close to each other, an area for arranging wires therein would lack, and hence, a lot of wires have to bypass a hard-macro. An area for arranging wires to bypass a hard-macro would cause a loss in a chip area and insufficient integration density of a semiconductor integrated circuit.

As mentioned above, it has been conventionally difficult to design a floor-plan, because it was difficult to estimate a necessary area for arranging wires therein.

Japanese Patent Application Publication No. 2-155254 (A) has suggested a device for designing an integrated circuit, including a hierarchy-layout designer. The hierarchy-layout designer includes first means for determining arrangement of cells in an integrated circuit, and paths of signal lines extending between the cells, second means for a number of wires passing through each of the cells, and third means for designing a layout of the cells.

Japanese Patent Application Publication No. 5-198673 (A) has suggested a semiconductor integrated circuit including a first wire vertically passing through a cell, and a second wire electrically connected to the first wire and horizontally passing through the cell.

### SUMMARY OF THE INVENTION

In view of the above-mentioned problems in the prior art, it is an object of the present invention to provide a hard-macro which is capable of providing a solution to the problem that a wire cannot pass through an area in which a hard-macro has been already arranged, minimizing an area for arranging wires therein, and making it possible to estimate a necessary area for arranging wires therein to thereby ensure designing a floor-plan.

It is also an object of the present invention to provide a semiconductor integrated circuit including such a hard-macro as mentioned above, a floor-planner for analyzing a floor-plan of a semiconductor integrated circuit including such a hard-macro as mentioned above, and a program for causing a computer to analyze a floor-plan of a semiconductor integrated circuit including such a hard-macro as mentioned above.

Hereinbelow is described a hard-macro, a semiconductor integrated circuit, a floor-planner, and a program in accordance with the present invention through the use of reference numerals used in later described embodiments. The reference numerals are indicated only for the purpose of clearly showing correspondence between claims and the embodiments. It should be noted that the reference numerals are not allowed to use in the interpretation of claims of the present application.

In one aspect of the present invention, there is provided a hard-macro (1, 2, 100, 200, 300) arranged on a semiconductor chip (5) for constituting a part of a semiconductor integrated circuit, including at least one wire (11a-11f, 21a-21f, 204, 304) passing therethrough, wherein the wire (11a-11f, 21a-21f, 204, 304) is formed in the hard-macro (1, 2, 100, 200, 300) before the hard-macro (1, 2, 100, 200, 300) is arranged on the semiconductor chip (5), and the wire (11a-11f, 21a-21f, 204, 304) starts a first outer edge (12, 22, 202, 302) of the hard-macro (1, 2, 100, 200, 300) and terminates at a second outer edge (13, 14, 23, 24, 203, 303) of the hard-macro (1, 2, 100, 200, 300) intersecting with the first outer edge (12, 22, 202, 302).

For instance, the first and second outer edges (12, 22, 202, 302; 13, 14, 23, 24, 203, 303) are perpendicular to each other.

For instance, the first and second outer edges (12, 22, 202, 302; 13, 14, 23, 24, 203, 803) are adjacent to each other.

It is preferable that the wire (11a-11f, 204) is L-shaped.

It is preferable that the wire (21a-21f, 304) is linear.

The hard-macro (1, 2, 100, 200, 300) may have a cut-out (201, 301) including one of corners of the hard-macro (1, 2, 100, 200, 300), in which case, the wire (11a-11f, 21a-21f, 204, 304) extends along the cut-out (201, 301) between the first and second outer edges.

If the cut-out is rectangular, and the wire (11a-11f, 21a-21f, 204, 304) may be L-shaped.

The hard-macro (1, 2, 100, 200, 300) may further including a repeater (100) inserted in the wire (11a-11f, 21a-21f, 204, 304).

The hard-macro (1, 2, 100, 200, 300) may include a plurality of wires (11a-11f, 21a-21f, 204, 304) passing therethrough, in which case, at least one of the wires (11a-11f, 21a-21f, 204, 304) may include a repeater inserted therein.

It is preferable that the wires (11a-11f, 21a-21f, 204, 304) are equally spaced away from adjacent ones.

The wire (11a-11f, 21a-21f, 204, 304) may be divided into a plurality of portions each of which is arranged in each of a plurality of hierarchies (111-114) of the hard-macro (1, 2, 100, 200, 300).

The hard-macro may be a random access memory (RAM) (1) or a phase-locked loop (PLL) circuit (2).

In another aspect of the present invention, there is provided a semiconductor integrated circuit including a hard-macro (1, 2, 100, 200, 300) arranged on a semiconductor chip (5) for constituting a part of the semiconductor integrated circuit, including at least one wire (11a-11f, 21a-21f, 204, 304) passing therethrough, wherein the wire (11a-11f, 21a-21f, 204, 304) is formed in the hard-macro (1, 2, 100, 200, 300) before the hard-macro (1, 2, 100, 200, 300) is arranged on the semiconductor chip (5), and the wire (11a-11f, 21a-21f, 204, 304) starts a first outer edge (12, 22, 202, 302) of the hard-macro (1, 2, 100, 200, 300) and terminates at a second outer edge (13, 14, 23, 24, 203, 303) of the hard-macro (1, 2, 100, 200, 300) intersecting with the first outer edge.

For instance, the semiconductor integrated circuit is a cell base integrated circuit (CBIC).

In still another aspect of the present invention, there is provided a floor-planner (4) including a device (42) for analyzing a floor-plan of a semiconductor integrated circuit including a hard-macro (1, 2, 100, 200, 300) arranged on a semiconductor chip (5) for constituting a part of the semiconductor integrated circuit which hard-macro (1, 2, 100, 200, 300) includes at least One wire (11a-11f, 21a-21f, 204, 304) passing therethrough, wherein the wire (11a-11f, 21a-21f, 204, 304) is formed in the hard-macro (1, 2, 100, 200, 300) before the hard-macro (1, 2, 100, 200, 300) is arranged on the semiconductor chip (5), and the wire (11a-11f, 21a-21f, 204, 304) starts a first outer edge (12, 22, 202, 302) of the hard-macro (1, 2, 100, 200, 300) and terminates at a second outer edge (13, 14, 23, 24, 203, 303) of the hard-macro (1, 2, 100, 200, 300) intersecting with the first outer edge.

For instance, the device (42) analyzes a route of the wire (11a-11f, 21a-21f, 204, 304).

In yet another aspect of the present invention, there is provided a program for causing a computer to analyze a floor-plan of a semiconductor integrated circuit, wherein the semiconductor integrated circuit includes a hard-macro (1, 2, 100, 200, 300) arranged on a semiconductor chip (5) for constituting a part of the semiconductor integrated circuit which hard-macro (1, 2, 100, 200, 300) includes at least one wire (11a-11f, 21a-21f, 204, 304) passing therethrough, wherein the wire (11a-11f, 21a-21f, 204, 304) is formed in the hard-macro (1, 2, 100, 200, 300) before the hard-macro (1, 2, 100, 200, 800) is arranged on the semiconductor chip (5), and the wire (11a-11f, 21a-21f, 204, 304) starts a first outer edge (12, 22, 202, 302) of the hard-macro (1, 2, 100, 200, 300) and terminates at a second outer edge (13, 14, 23, 24, 203, 803) of the hard-macro (1, 2, 100, 200, 300) intersecting with the first outer edge.

It is preferable that the computer further analyzes a route of the wire (11a-11f, 21a-21f, 204, 304).

The advantages obtained by the aforementioned present invention will be described hereinbelow.

In the hard-macro in accordance with the present invention, a wire passing therethrough is formed before arrangement of the hard-macro onto a semiconductor chip. Hence, adjacent hard-macros can be electrically connected to each other through the wire. This means that the hard-macro in accordance with the present invention provides a solution to the problem that a hard-macro cannot pass through an area in which a hard-macro has been already arranged.

In addition, the hard-macro in accordance with the present invention can reduce a number of wires to be arranged between hard-macros, minimizing an area for arranging wires therein between hard-macros, and further making it possible to estimate a necessary area for arranging wires therein. Accordingly, a floor-plan of a semiconductor integrated circuit can be readily made.

Furthermore, designability in arrangement of wires can be enhanced, ensuring enhancement in designability of a layout of arrangement of wires and hard-macros. This also makes it possible to make a floor-plan of a semiconductor integrated circuit with ease.

Since an area in which wires are arranged between hard-macros can be minimized, it would be possible to minimize a chip area, and to increase an integration density of a semiconductor integrated circuit.

Furthermore, since it is possible to minimize a wire length by making use of the wire formed in the hard-macro, timing convergence can be readily accomplished. As a result, it is no longer necessary to make a layout again, and it is possible to shorten a turn-around-time (TAT).

In the hard-macro in accordance with the present invention, the wire passing through the hard-macro is designed to extend a first outer edge of the hard-macro to a second outer edge of the hard-macro intersecting with the first outer edge, when viewed perpendicularly. Hence, a wire which is necessary to extend between the first and second outer edges of the hard-macro can be made by using the wire passing through the hard-macro. Thus, it is possible to minimize a space between the hard-macro in accordance with the present invention and other hard-macros located in the vicinity of the first or second outer edge of the hard-macro.

Since the semiconductor integrated circuit in accordance with the present invention includes the above-mentioned hard-macro, the semiconductor integrated circuit can have a high integration density, and can be fabricated in a short TAT, because a floor-plan can be readily made.

Since the floor-planner in accordance with the present invention has a device for analyzing a floor-plan of a semiconductor integrated circuit including the above-mentioned hard-macro, it is possible to make a floor-plan making use of the wires formed in the hard-macro.

The above and other objects and advantageous features of the present invention will be made apparent from the following description made with reference to the accompanying drawings, in which like reference characters designate the same or similar parts throughout the drawings.

### BRIEF DESCRIPTION OF THE DRAWINGS

FIG. 1 is a partial plan view of a conventional semiconductor integrated circuit.

FIG. 2 is a plan view of a hard-macro in accordance with the first embodiment of the present invention.

FIG. 8 is a perspective view of a hierarchy structure of the hard-macro illustrated in FIG. 2.

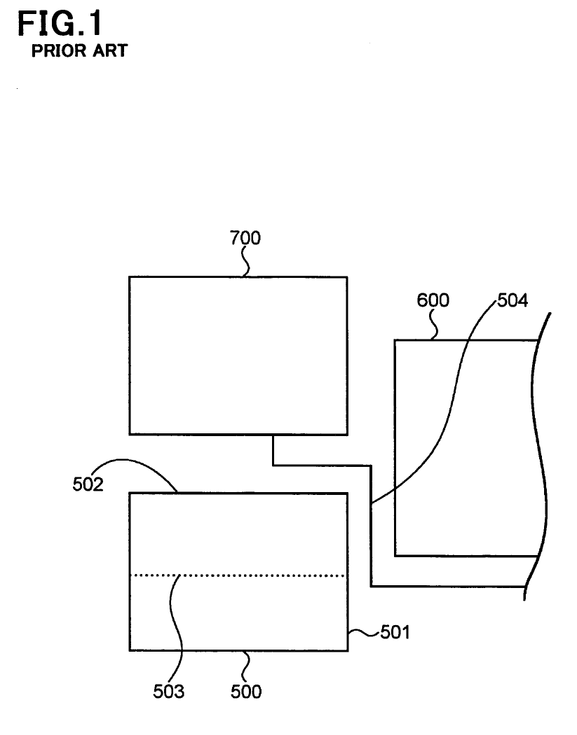

FIG. 4 is a plan view of a hard-macro in accordance with the first embodiment of the present invention.

FIG. 5 is a plan view of a semiconductor integrated circuit in accordance with the first embodiment of the present invention.

FIG. 6 is a block diagram of a floor-planner in accordance with the second embodiment of the present invention.

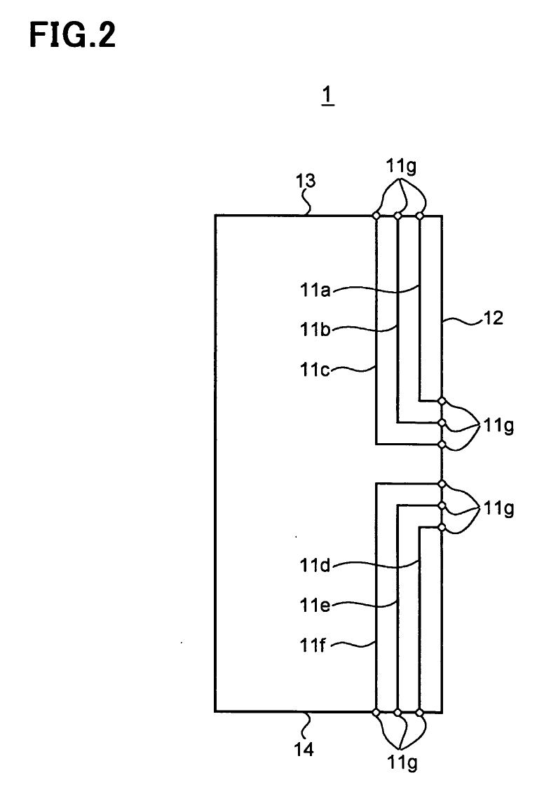

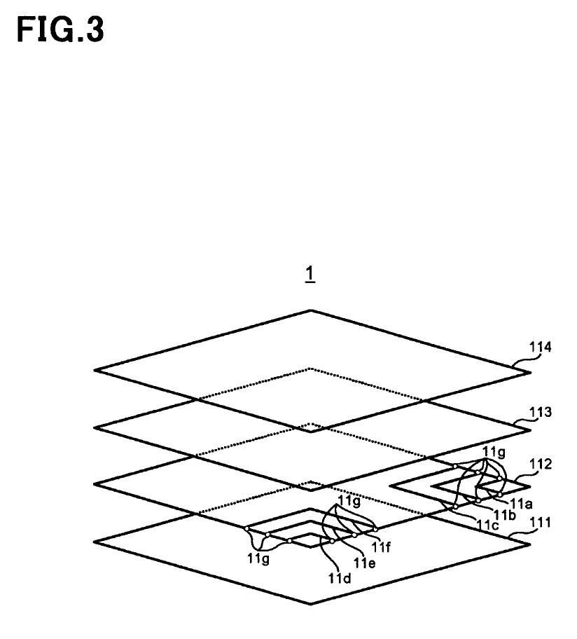

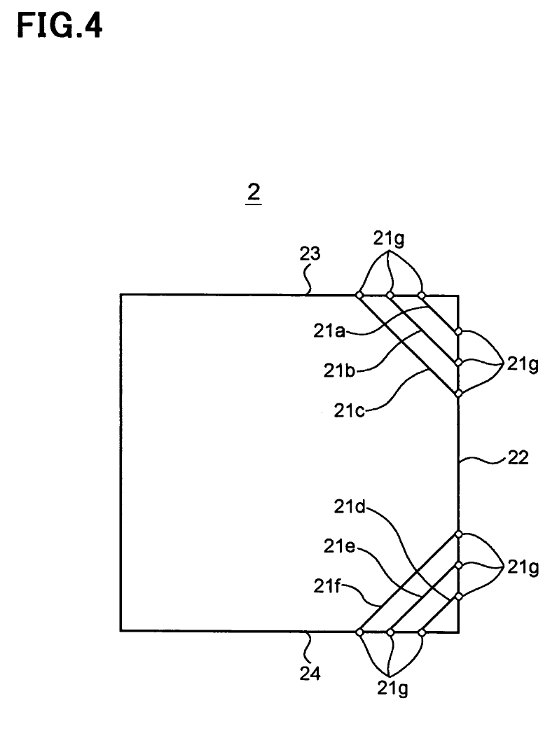

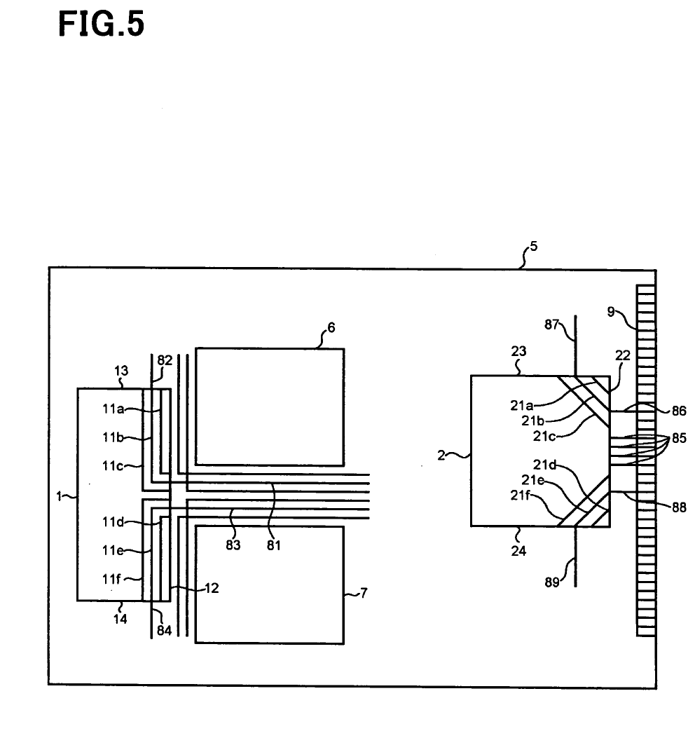

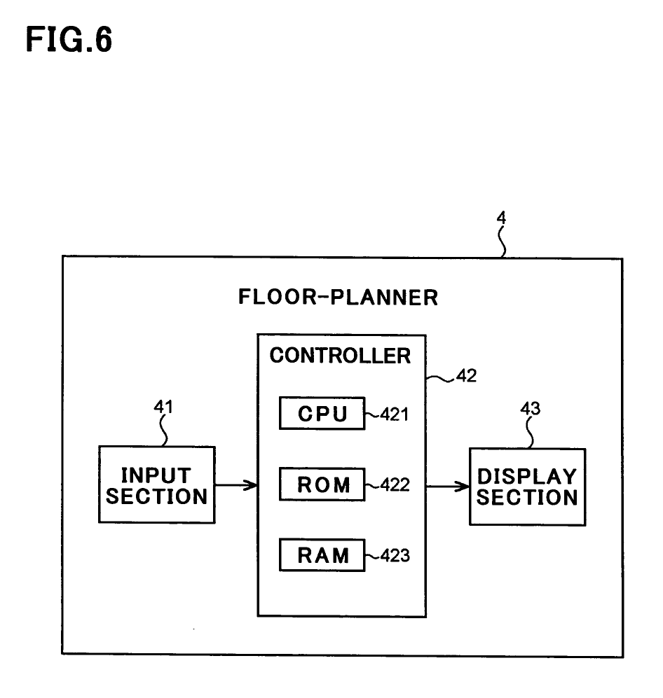

FIG. 7 is a perspective view of another hierarchy structure of the hard-macro illustrated in FIG. 2.

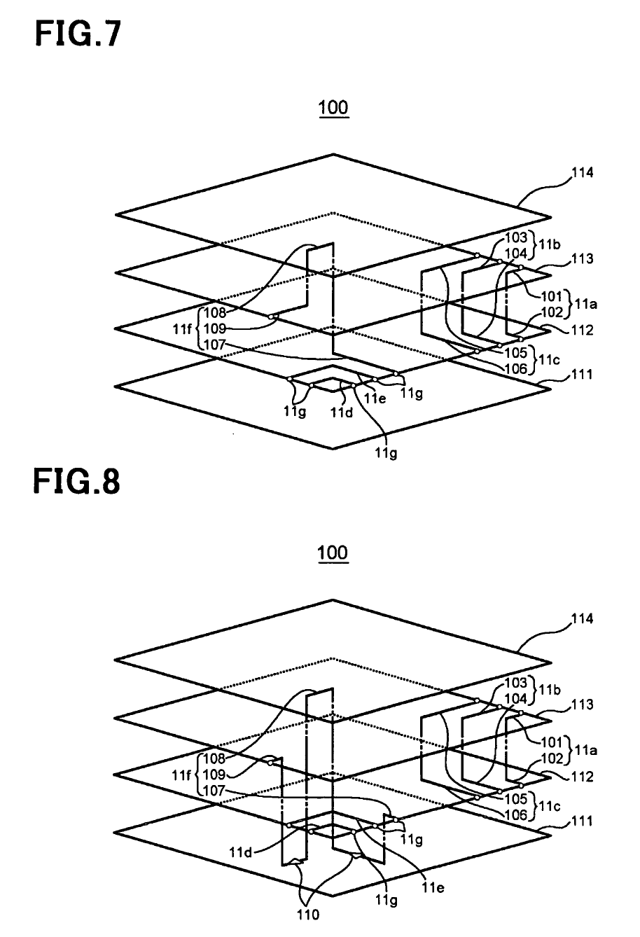

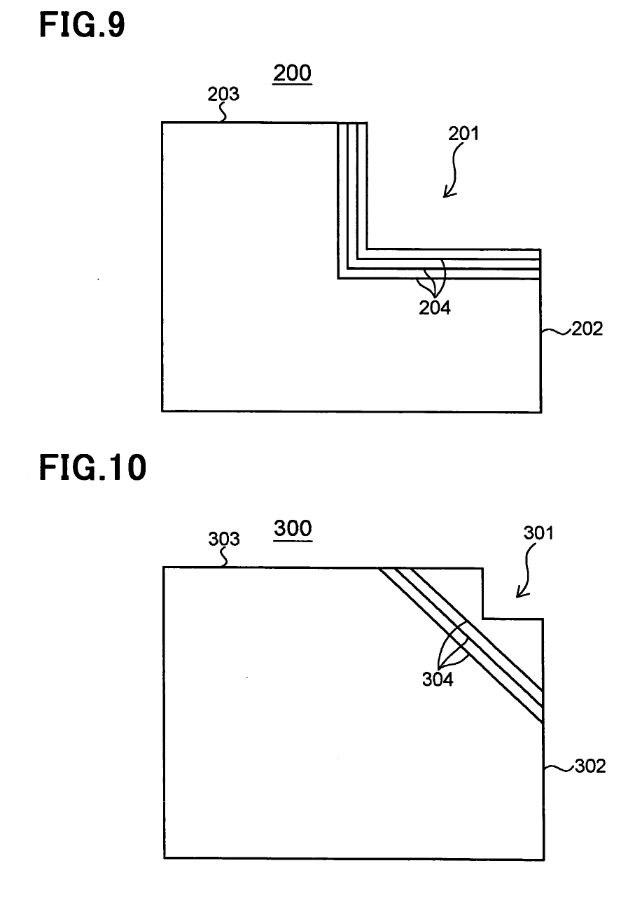

FIG. 8 is a perspective view of still another hierarchy structure of the hard-macro illustrated in FIG. 2.

FIG. 9 is a plan view of a hard-macro in accordance with an example of the first embodiment of the present invention.

FIG. 10 is a plan view of a hard-macro in accordance with another example of the first embodiment of the present invention.

### DESCRIPTION OF THE PREFERRED EMBODIMENTS

Preferred embodiments in accordance with the present invention will be explained hereinbelow with reference to drawings.

[First Embodiment]

FIGS. 2 to 5 illustrate hard-macros in accordance with the first embodiment of the present invention. FIG. 2 is a plan view of a random access memory (RAM) 1 as a first example of a hard-macro in accordance with the first embodiment, FIG. 3 is a perspective view of a hierarchy structure of the RAM 1 illustrated in FIG. 2, FIG. 4 is a plan view of a phase locked loop (PLL) circuit 2 as a second example of a hard-macro in accordance with the first embodiment, and FIG. 5 is a plan view of a cell base integrated circuit (CBIC) on which the RAM 1 and the PLL circuit 2 are arranged.

As illustrated in FIG. 4, the RAM 1 and the PLL circuit 2 are arranged on a semiconductor chip 5, and constitute a part of a cell base integrated circuit (CBIC).

As illustrated in FIG. 2, a plurality of wires 11a, 11b, 11c, 11d, 11e and 11f passing through inside of the RAM 1 is formed on or in the RAM 1. The wires 11a to 11f are formed before the RAM 1 is arranged onto the semiconductor chip 5.

The RAM 1 is rectangular when viewed perpendicularly. The wires 11a to 11c are designed to be L-shaped, and to extend from a first outer edge 12 of the RAM 1 to a second outer edge 13 of the RAM 1 intersecting with the first outer edge 12. Similarly, the wires 11d to 11f are designed to be L-shaped, and to extend from the first outer edge 12 to a third outer edge 14 of the RAM 1 intersecting with the first outer edge 12.

Specifically, the second and third outer edges 13 and 14 are located adjacent to and perpendicularly intersect with the first outer edge 12. The L-shaped wires 11a to 11f pass inside the RAM 1. The wires 11a to 11c are spaced away from one another at a constant pitch equal to a slot pitch, and similarly, the wires 11d to 11f are spaced away from one another at a constant pitch equal to a slot pitch.

Each of the wires 11a to 11f is connected at opposite ends thereof with terminals 11g through which each of the wires 11a to 11f is electrically connected to an external wire (not illustrated).

As illustrated in FIG. 3, the RAM 1 has a hierarchy structure comprised of a plurality of hierarchies. The RAM 1 in the first embodiment has a hierarchy structure comprised of first to fourth layers 111 to 114. The wires 11a to 11f in the RAM 1 are all arranged on the second layer 112. However, as explained later, the wires 11a to 11f may be arranged on a plurality of the layers.

Herein, what is meant by the term “a plurality of hierarchies” is explained. The RAM 1 as a hardware macro can be formed by electrically connecting parts (for instance, transistors) arranged on a semiconductor substrate to one another through a wiring layer. A wiring layer is generally designed to have a multi-layered structure, and is used as a wire arranged in a hard-macro or a wire extending between adjacent hard-macros. The wires 11a to 11f in the first embodiment indicate wires having no electrical connection with the RAM 1.

As illustrated in FIG. 4, a plurality of wires 21a, 21b, 21c, 21d, 21e and 21f passing through inside of the PLL circuit 2 is formed on or in the PLL circuit 2. The wires 21a to 21f are formed before the PLL circuit 2 is arranged onto the semiconductor chip 5.

The PLL circuit 2 is rectangular when viewed perpendicularly. The wires 21a to 21c are designed to diagonally extend from a first outer edge 22 of the RAM 1 to a second outer edge 23 of the PLL circuit 2 intersecting with the first outer edge 22. Similarly, the wires 21d to 21f are designed to be L-shaped, and to extend from the first outer edge 22 to a third outer edge 24 of the PLL circuit 2 intersecting with the first outer edge 22.

Specifically the second and third outer edges 23 and 24 are located adjacent to and perpendicularly intersect with the first outer edge 22. The wires 21a to 21f are in the form of a line, and pass inside the PLL circuit 2. The wires 21a to 21c are spaced away from one another at a constant pitch equal to a slot pitch, and similarly, the wires 21d to 21f are spaced away from one another at a constant pitch equal to a slot pitch.

Each of the wires 21a to 21f is connected at opposite ends thereof with terminals 21g through which each of the wires 21a to 21f is electrically connected to an external wire (not illustrated).

The PLL circuit 2 is designed to have hierarchy structure comprised of a plurality of hierarchies, similarly to the RAM 1, and the wires 21a to 21f are arranged on one of the hierarchies.

Hereinbelow, arrangement of the RAM 1 and the PLL circuit 2 onto the semiconductor chip 5 is explained with reference to FIG. 5.

Since the RAM 1 has the wires 11a to 11f passing therethrough, it is possible to arrange signal lines through the wires 11a to 11f. In comparison with a RAM not having the wires 11a to 11f, it is possible to narrow a distance between the RAM 1 and a RAM 6 and a distance between the RAM 1 and a RAM 7.

For instance, it is assumed that a wire 81 facing the first outer edge 12 of the RAM 1 is electrically connected to a wire 82 facing the second outer edge 13 of the RAM 1. The RAM 1 in accordance with the first embodiment makes it possible for the wires 81 and 82 to be electrically connected to each other without bypassing the RAM 1, by connecting the wires 81 and 82 to the wire 11b.

In contrast, in a conventional RAM not having the wires 11a to 11f, it would be necessary to connect the wires 81 and 82 to each other through a wire extending along the first and second outer edges 12 and 13 to bypass the RAM 1. Thus, a distance between the conventional RAM and the RAM 6 is unavoidably greater than a distance between the RAM 1 and the RAM 6.

The same as mentioned above is applied to a case where a wire 83 facing the first outer edge 12 of the RAM 1 is electrically connected to a wire 84 facing the third outer edge 14 of the RAM 1.

As mentioned above, in accordance with the RAM 1, a plurality of the wires 11a to 11f passing through the RAM 1 is arranged in the RAM 1 before the RAM 1 is arranged onto the semiconductor chip 5. Hence, it is possible to design wire arrangement by making use of the wires 11a to 11f. Thus, it is possible to solve the problem that a wire cannot pass through an area in which the RAM 1 is mounted.

In addition, since a number of wires to be arranged in a space between the RAM 1 and the RAMs 6 and 7 can be reduced, a necessary area between the spaces can be minimized. This ensures that a distance between the RAM 1 and the RAMs 6 and 7 can be narrowed. Accordingly, the RAMs 1, 6 and 7 can be arranged in a narrow area, ensuring a sufficient integration density of CBIC and minimization of an area of the semiconductor chip 5.

Furthermore, since a number of wires to be arranged in a space between the RAM 1 and the RAMs 6 and 7 can be reduced, it would be possible to estimate a necessary area between the RAM 1 and the RAMs 6 and 7, ensuring that a floor-plan of CBIC can be made, and TAT is shortened. In addition, designability in arrangement of wires can be enhanced by making use of the wires 11a to 11f, ensuring enhancement in designability of a layout of arrangement of wires and hard-macros. This also makes it possible to make a floor plan of CBIC.

Furthermore, since it is possible to minimize a wire length by making use of the wires 11a to 11f, timing convergence can be readily accomplished. As a result, it is no longer necessary to make a layout again, and it is possible to shorten TAT.

Since the wires 11a to 11f are designed to extend between the first outer edge 12 and the second and third outer edges 13 and 14, the wires 81 and 82 can be connected to each other through the wire 11b, and the wires 83 and 84 can be connected to each other through the wire 11e. Hence, it is possible to minimize distances between the RAM 1 and the hard-macros (RAMs) 6 and 7 located facing the first outer edge 12 of the RAM 1, and further, distances between the RAM 1 and the hard-macros (not illustrated) located facing the second and third outer edges 13 and 14 of the RAM 1.

Since the PLL circuit 2 includes the wires 21a to 21f passing therethrough, it is possible to arrange a wire or wires by making use of the wires 21a to 21f. Accordingly, in comparison with a conventional PLL circuit not having the wires 21a to 21f, it is possible to narrow a distance between the PLL circuit and an I/O pad 9.

The PLL circuit 2 is electrically connected at a first outer edge 22 to the I/O pad 9 through a plurality of wires 85.

For instance, it is assumed that a wire 86 extending between the I/O pad 9 and the first outer edge 22 of the PLL circuit 2 is electrically connected to a wire 87 facing a second outer edge 23 of the PLL circuit 2. As illustrated in FIG. 5, the PLL circuit 2 in accordance with the first embodiment makes it possible for the wires 86 and 87 to be electrically connected to each other without bypassing the PLL circuit 2, by connecting the wires 86 and 87 to the wire 21b.

It is assumed that a wire 88 extending between the I/O pad 9 and the first outer edge 22 of the PLL circuit 2 is electrically connected to a wire 89 facing a third outer edge 24 of the PLL circuit 2. Similarly, the PLL circuit 2 makes it possible for the wires 88 and 89 to be electrically connected to each other without bypassing the PLL circuit 2, by connecting the wires 88 and 89 to the wire 21e.

As mentioned above, since the PLL circuit 2 includes the wires 21a to 21f passing therethrough which wires are arranged in the PLL circuit 2 prior to the arrangement of the PLL circuit 2 onto the semiconductor chip 5, the PLL circuit 2 provides the same advantages as those presented by the RAM 1. Thus, the PLL circuit 2 can be located closer to the I/O pad 9 than a conventional PLL circuit.

Furthermore, since the wires 21a to 21f are designed to be linear, the wire 86 facing the first outer edge 22 of the PLL circuit 2 can be connected to the wire 87 facing the second outer edge 23 through the wire 21b by a minimum length. Similarly, the wire 88 facing the first outer edge 22 of the PLL circuit 2 can be connected to the wire 89 facing the third outer edge 24 through the wire 21e by a minimum length.

Since the cell base integrated circuit (CBIC) includes the RAM 1 and the PLL circuit 2, the cell base integrated circuit can have a high integration density and can be fabricated in a short turn-around-time (TAT), because a floor-plan of the cell base integrated circuit can be readily made.

[Second Embodiment]

FIG. 6 is a block diagram of a floor-planner 4 in accordance with the second embodiment of the present invention.

The floor-planner 4 is comprised of a computer-aided design (CAD), for instance. Specifically, the floor-planner 4 is comprised of an input section 41, a controller 42, and a display section 48.

The display section 43 displays a layout of a semiconductor integrated circuit such as CBIC, or graphic guidance for a user to input parameters under control of the controller 42. For instance, the display section 48 is comprised of a cathode ray tube (CRT) or a liquid crystal display (LCD) device.

An operator can input a request of making a floor-plan or various parameters into the controller 42 through the input section 41. The input section 41 is comprised of a keyboard or a mouse, for instance.

The controller 42 carries out various functions and controls in accordance with signal inputs an operator has input through the input section 41. As illustrated in FIG. 6, the controller 42 is comprised of a central processing unit (CPU) 421, a read only memory (ROM) 422, and a random access memory (RAM) 423.

The central processing unit 421 executes a control program stored in the read only memory 422 to carry out various controls. The read only memory 422 stores a control program for making a floor-plan, to be executed by the central processing unit 421, and various data. The random access memory 423 has a storage area in which various data is temporarily stored, and an operation area used by the central processing unit 421 for operation thereof.

Specifically, the central processing unit 421 executes a program for making a floor-plan, stored in the read only memory 422, in accordance with commands input by an operator, to thereby carry out analysis of a floor-plan. The analysis of a floor-plan includes analysis of arrangement of hard-micros and wires.

The central processing unit 421 analyzes where hard-micros should be positioned, and then, determines arrangement of hard-micros. It is preferable that such analysis and decision about where hard-micros should be positioned are carried out in parallel with analysis and decision-about where wires should be positioned. In other words, positions of hard-micros are determined in accordance with whether wires can be appropriately arranged.

The analysis of arrangement of wires carried out by the central processing unit 421 includes analysis about arrangement of wires formed in hard-micros, such as the wires 11a to 11f and 21a to 21f.

In the analysis of arrangement of wires, there are analyzed and determined whether the wires 11a to 11b are used when the RAM 1 is mounted on the semiconductor chip 5, and which wire among the wires 81 to 84 should be connected to which wire among the wires 11a to 11f For instance, when the wires 81 and 83 are connected to the wires 82 and 84, respectively, the central processing unit 421 determines using one of the wires 11a to 11f for connecting the wires 81 and 83 to the wires 82 and 84, respectively, because the RAM 1 is located between the wires 81, 83 and the wires 82, 84. Then, the central processing unit 421 analyzes which combination is optimal among combinations of any one of the wires 81 to 84 and any one of the wires 11a to 11f, and determines the most optimal combination of one of the wires 81 to 84 and one of the wires 11a to 11f. For instance, the wires 81 and 82 can be connected in a minimum wire length to each other through the wire 11b without unnecessary crank in a wire route, and that the wires 83 and 84 can be connected in a minimum wire length to each other through the wire 11e without unnecessary crank in a wire route. Accordingly, the central processing unit 421 selects the wire 11b used for connecting the wires 81 and 82 to each other therethrough, and the wire 11e used for connecting the wires 83 and 84 to each other therethrough.

Similarly, when the wires 86 and 88 are connected to the wires 87 and 89, respectively, the central processing unit 421 determines using one of the wires 21a to 21f for connecting the wires 86 and 88 to the wires 87 and 89, respectively, because the PLL circuit 2 is located between the wires 86, 88 and the wires 87, 89. Then, the central processing unit 421 analyzes which combination is optimal among combinations of any one of the wires 86 to 89 and any one of the wires 21a to 21f, and determines the most optimal combination of one of the wires 86 to 89 and one of the wires 21a to 21f. For instance, the wires 86 and 87 can be connected in a minimum wire length to each other through the wire 21b without unnecessary crank in a wire route, and that the wires 88 and 89 can be connected in a minimum wire length to each other through the wire 21e without unnecessary crank in a wire route. Accordingly, the central processing unit 421 selects the wire 21b used for connecting the wires 86 and 87 to each other therethrough, and the wire 21e used for connecting the wires 88 and 89 to each other therethrough.

As is obvious in view of the explanation made above, the controller 42 acts as a floor-plan analyzer.

As mentioned above, since the floor-planner 4 includes the controller 42 acting as a floor-plan analyzer, the floor-planner 4 can analyze and determine arrangement of hard-macros such as the RAM 1 and the PLL circuit 2, whether the wires 11a to 11f or 21a to 21f should be used when hard-macros are arranged onto the semiconductor chip 5, and which combination is optimal among combinations of any one of the wires 81 to 84 (or 86 to 89) and any one of the wires 11a to 11f (or 21a to 21f). Thus, it is possible to optimally arrange hard-macros on the semiconductor chip 5, and optimally use the wires 11a to 11f (or 21a to 21f).

As mentioned earlier, the reasons why a wire cannot be arranged in an area in which a hard-macro is mounted include cross-talk between the wire and cells constituting a hard-macro, and short-circuit of the wire with wires arranged in a hard-macro. In a conventional hard-macro, if a wire was additionally formed to a hard-macro which had been once optimally designed, the hard-macro had to be re-designed.

In contrast, since the hard-macro in accordance with the first embodiment of the present invention is designed to include wires passing therethrough, such as the wires 11a to 11f, it is possible to solve the above-mentioned problem found in a conventional hard-macro. In particular, when it is necessary to turn wires to a different direction in an area in which a hard-macro is formed, the hard-macro in accordance with the first embodiment of the present invention makes it possible to turn wires to a desired direction.

### EXAMPLE 1

In the above-mentioned RAM 1, the wires 11a to 11f are arranged on only one of the hierarchies constituting the RAM 1. Specifically, the wires 11a to 11f are arranged on the second layer 112 among the first to fourth layers 111 to 114. However, it should be noted that the wires 11a to 11f might be arranged on two or more of the hierarchies 111 to 114.

FIG. 7 illustrates a first variant of the RAM 1. Parts or elements that correspond to those of the RAM 1 illustrated in FIG. 3 have been provided with the same reference numerals.

As illustrated in FIG. 7, the wire 11a in a RAM 100 in accordance with the first example is divided into a first portion 102 arranged on the second layer 112 and a second portion 101 arranged on the third layer 113. The first and second portions 102 and 103 are electrically connected to each other through a via-contact (not illustrated) formed throughout an interlayer insulating film (not illustrated) sandwiched between the second and third layers 112 and 113 for electrically isolating them from each other. Herein, a via-contact is comprised of electrical conductor filing therewith a via-hole formed throughout an interlayer insulating film. In FIG. 7, two-dot chain lines extending perpendicularly to the second and third layers 112 and 113 indicate via-contacts.

Hereinbelow, unless otherwise indicated, portions of the wires arranged on each of the first to fourth layers 111 to 114 are electrically connected to each other through a via-contact indicated with two-dot chain lines.

With reference to FIG. 7, the wire 11a is divided into the first portion 101 and the second portion 102, and the first and second portions 101 and 102 are arranged on the third and second layers 113 and 112, respectively.

Similarly, the wire 11b is divided into a first portion 103 and a second portion 104, and the first and second portions 103 and 104 are arranged on the third and second layers 113 and 112, respectively. The wire 11c is divided into a first portion 105 and a second portion 106, and the first and second portions 105 and 106 are arranged on the third and second layers 113 and 112, respectively.

The wire 11f is divided into a first portion 107, a second portion 108 and a third portion 109, and the first, second and third portions 107, 108 and 109 are arranged on the second, fourth and third layers 112, 114 and 113, respectively.

If a wire such as the wire 11f is designed to be arranged on a plurality of layers or to have a long wire length, a repeater or buffer 110 may be inserted into the wire, as illustrated in FIG. 8.

The repeater 110 is a circuit comprised of two inverters electrically connected in series to each other. By designing a wire such as the wire 11f to have the repeater 110, it is possible to control signal delay in the wire.

A wire such as the wire 11f may be designed to include a plurality of the repeaters 110 arranged in series, or a single repeater 110.

For instance, if the wire 11f is designed to have a long wire length, a first repeater 110 is arranged in the vicinity of the terminal 11g located at one end of the wire 11f. A signal having been input to the terminal 11g is transmitted to the wire 11f through the first repeater 110. A second repeater 110 is arranged in the vicinity of the terminal 11g located at the other end of the wire 11f. The signal is transmitted through the second repeater 110, and output through the latter terminal 11g.

As is known to those skilled in the art, a repeater outputs a signal having the same phase as that of an input signal for preventing signal delay in a long wire. The repeater 110 illustrated in FIG. 8 is not electrically connected to the RAM 1. As mentioned above, a repeater is comprised generally of a circuit comprised of two inverters electrically connected in series to each other. An inverter can be formed by electrically connecting devices formed on a semiconductor substrate, such as transistors, to each other through a wiring layer. In FIG. 8, the two repeaters 110 are illustrated to be arranged on the first layer 111. This means just electrical connection of the repeaters 110 with wires formed in the first layer 111, and does not always mean that the repeaters 110 are formed of wiring layers of the first layer 111.

### EXAMPLE 2

The above-mentioned RAM 1 and PLL circuit 2 are rectangular and have the first outer edges 12 and 22 and the second and third edges 13, 14 and 23, 24 located adjacent to the first outer edges 12 and 22, respectively.

FIG. 9 illustrates a hard-macro 200 as a second variant of the RAM 1. In the second example, a hard-macro such as the RAM 1 has a cut-out including one of corners, and hence, an edge of the hard-macro is not adjacent to other edges.

As illustrated in FIG. 9, the hard-macro 200 has a rectangular cut-out 201 including a corner of the hard-macro 200. As a result, a first outer edge 202 and a second outer edge 203 of the hard-macro 200 are not adjacent to each other. The hard-macro 200 has L-shaped wires 204 extending along the rectangular cut-out 201 between the first and second outer edges 202 and 203.

FIG. 10 illustrates a hard-macro 300 as a third variant of the RAM 1.

As illustrated in FIG. 10, the hard-macro 300 has a rectangular cut-out 301 including a corner of the hard-macro 300. As a result, a first outer edge 302 and a second outer edge 303 of the hard-macro 300 are not adjacent to each other. The hard-macro 300 has linear wires 304 extending between the first and second outer edges 302 and 303, and not intersecting with the cut-out 301.

In accordance with the hard-macro 200 (or 300), it is possible to arrange a wire extending through the first outer edge 202 (or 302) and the second outer edge 203 (or 303) by making use of the wires 204 (or 304). That is, the hard-macros 200 and 300 provide the same advantages as those presented by the above-mentioned RAM 1 and the PLL circuit 2 in accordance with the first embodiment.

The wires 11a to 11f, 21a to 21f, 204 and 304 are designed L-shaped or linear. However, it should be noted that they may be designed to be curved, zigzagged, or cranked.

Though the above-mentioned RAM 1 and the PLL circuit 2 are designed to have a plurality of wires 11a to 11f and 21a to 21f, respectively, they may be designed to have a single wire passing therethrough.

In the above-mentioned embodiments, CBIC is explained as an example of a semiconductor integrated circuit. However, other building-block type semiconductor integrated circuits may be used in place of CBIC.

The controller 42 may be designed to include other recording mediums in place of the ROM 422. Herein, the term “recording medium” means any medium which can record data therein.

The term “recording medium” includes, for instance, a disk-shaped recorder such as CD-ROM (Compact Disk-ROM) or PD, a magnetic tape, MO (Magneto Optical Disk), DVD-ROM (Digital Video Disk-Read Only Memory), DVD-RAM (Digital Video Disk-Random Access Memory), a flexible disk, a memory chip such as RAM (Random Access Memory) or ROM (Read Only Memory), EPROM (Erasable Programmable Read Only Memory), EEPROM (Electrically Erasable Programmable Read Only Memory), smart media (Registered Trade Mark), a flush memory, a rewritable card-type ROM such as a compact flush card, a hard disk, and any other suitable means for storing a program therein.

In place of the ROM 422, the controller 42 may include a memory which can be inserted into or taken out of the floor-planner 4.

While the present invention has been described in connection with certain preferred embodiments, it is to be understood that the subject matter encompassed by way of the present invention is not to be limited to those specific embodiments. On the contrary, it is intended for the subject matter of the invention to include all alternatives, modifications and equivalents as can be included within the spirit and scope of the following claims.

The entire disclosure of Japanese Patent Applications Nos. 2003-107682 and 2004-062213 filed on April 11, 2003 and Mar. 5, 2004, respectively, including specification, claims, drawings and summary is incorporated herein by reference in its entirety.

What is claimed is:

1. A hard-macro arranged on a semiconductor chip for constituting a part of a semiconductor integrated circuit, including at least one wire passing therethrough, wherein said wire is formed in said hard-macro before said hard-macro is arranged on said semiconductor chip, and said wire starts a first outer edge of said hard-macro and terminates at a second outer edge of said hard-macro intersecting with said first outer edge.

2. The hard-macro as set forth in claim 1, wherein said first and second outer edges are perpendicular to each other.

3. The hard-macro as set forth in claim 1, wherein said first and second outer edges are adjacent to each other.

4. The hard-macro as set forth in claim 1, wherein said wire is L-shaped.

5. The hard-macro as set forth in claim 1, wherein said wire is linear.

6. The hard-macro as set forth in claim 1, wherein said hard-macro has a cut-out including one of corners of said hard-macro, and said wire extends along said cut-out between said first and second outer edges.

7. The hard-macro as set forth in claim 6, wherein said cut-out is rectangular, and said wire is L-shaped.

8. The hard-macro as set forth in claim 1, further including a repeater inserted in said wire.

9. The hard-macro as set forth in claim 1, wherein said hard-macro includes a plurality of wires passing therethrough.

10. The hard-macro as set forth in claim 9, wherein said wires are equally spaced away from adjacent ones.

11. The hard-macro as set forth in claim 9, wherein at least one of said wires includes a repeater inserted therein.

12. The hard-macro as set forth in claim 1, wherein said wire is divided into a plurality of portions each of which is arranged in each of a plurality of hierarchies of said hard-macro.

13. The hard-macro as set forth in claim 1, wherein said hard-macro is a random access memory (RAM).

14. The hard-macro as set forth in claim 1, wherein said hard-macro is a phase-locked loop (PLL) circuit.

15. A semiconductor integrated circuit including a hard-macro arranged on a semiconductor chip for constituting a part of said semiconductor integrated circuit, including at least one wire passing therethrough, wherein said wire is formed in said hard-macro before said hard-macro is arranged on said semiconductor chip, and said wire starts a first outer edge of said hard-macro and terminates at a second outer edge of said hard-macro intersecting with said first outer edge.

16. The semiconductor integrated circuit as set forth in claim 15, wherein said semiconductor integrated circuit is a cell base integrated circuit (CBIC).

17. A floor-planner including a device for analyzing a floor-plan of a semiconductor integrated circuit including a hard-macro arranged on a semiconductor chip for constituting a part of said semiconductor integrated circuit which hard-macro includes at least one wire passing therethrough, wherein said wire is formed in said hard-macro before said hard-macro is arranged on said semiconductor chip, and said wire starts a first outer edge of said hard-macro and terminates at a second outer edge of said hard-macro intersecting with said first outer edge.

18. The floor-plan as set forth in claim 17, wherein said device analyzes a route of said wire.

19. A program for causing a computer to analyze a floor-plan of a semiconductor integrated circuit, wherein said semiconductor integrated circuit includes a hard-macro arranged on a semiconductor chip for constituting a part of said semiconductor integrated circuit which hard-macro includes at least one wire passing therethrough, wherein said wire is formed in said hard-macro before said hard-macro is arranged on said semiconductor chip, and said wire starts a first outer edge of said hard-macro and terminates at a second outer edge of said hard-macro intersecting with said first outer edge.

20. The program as set forth in claim 19, wherein said computer further analyzes a route of said wire.
